(19) United States
(12) Patent Application Publication
(10) Pub. No.: US 2025/0160134 A1
(43) Pub. Date: May 15, 2025

(54) DISPLAY PANEL AND MANUFACTURING METHOD THEREOF

(71) Applicant: Samsung Display Co., LTD., Yongin-si (KR)

(72) Inventors: HYUNEOK SHIN, Yongin-si (KR); BYUNG SOO SO, Yongin-si (KR); SEUNGYONG SONG, Yongin-si (KR); SUNGSOON IM, Yongin-si (KR); KEUNHO JANG, Yongin-si (KR); YUNG BIN CHUNG, Yongin-si (KR); YU-GWANG JEONG, Yongin-si (KR); WOOJIN CHO, Yongin-si (KR)

(21) Appl. No.: 18/923,501

(22) Filed: Oct. 22, 2024

(30) Foreign Application Priority Data
Nov. 15, 2023 (KR) 10-2023-0157944

(51) Int. Cl. H10K 59/122; H10K 59/00; H10K 59/12; H10K 59/80

(52) U.S. Cl. CPC H10K 59/122; H10K 59/1201; H10K 59/771; H10K 59/873

(57) ABSTRACT

A display panel includes a base layer, and a light emitting element layer having a plurality of light emitting regions spaced apart from each other and a non-light emitting region. The light emitting element layer includes a first electrode, a pixel-defining film, a hole transport region, a light emitting layer to correspond to the plurality of light emitting regions, an electron transport region, and a second electrode. The electron transport region integrally overlaps the plurality of light emitting regions and the non-light emitting region, and the hole transport region does not overlap at least a portion of the non-light emitting region.

### CROSS-REFERENCE TO RELATED APPLICATIONS

The present application claims priority to and the benefit of Korean Patent Application No. 10-2023-0157944, filed on Nov. 15, 2023, in the Korean Intellectual Property Office, the entire disclosure of which is incorporated herein by reference.

### BACKGROUND

### 1. Field

Aspects of some embodiments of the present disclosure herein relate to a display panel and a manufacturing method thereof.

### 2. Description of the Related Art

Display devices are used in various multimedia apparatuses such as televisions, mobile phones, tablet computers, game consoles, or the like so as to display image information to a user.

A display device includes a display module and a window module. A window that is included in the display device effectively transmits image information, which is provided by the display module, to the outside and protects the display module from the outside.

The display module includes a light emitting element layer, and the light emitting element layer includes a first electrode, a second electrode, and a light-emitting layer. In addition, the light emitting element layer may further include functional layers such as a hole transport region, an electron transport region, and the like.

The above information disclosed in this Background section is only for enhancement of understanding of the background and therefore the information discussed in this Background section does not necessarily constitute prior art.

### SUMMARY

Aspects of some embodiments of the present disclosure herein relate to a display panel and a manufacturing method thereof, and for example, to a display panel having a structure in which moisture permeation and oxidation of a light emitting element are prevented or reduced, and a manufacturing method thereof.

Aspects of some embodiments of the present disclosure include a display panel with relatively improved reliability by having a structure in which moisture permeation and oxidation are prevented or reduced, and a manufacturing method thereof.

According to some embodiments of the present disclosure, a display panel includes: a base layer; and a light emitting element layer on the base layer, and including a plurality of light emitting regions spaced apart from each other on a plane (or in a plan view) and a non-light emitting region configured to surround each of the plurality of light emitting regions, wherein the light emitting element layer includes: a first electrode on the base layer to correspond to the plurality of light emitting regions; a pixel-defining film, in which openings corresponding to the plurality of light emitting regions are defined, and which is on the base layer; a hole transport region on the first electrode; a light emitting layer on the hole transport region to correspond to the plurality of light emitting regions; an electron transport region on the light emitting layer; and a second electrode on the electron transport region, the electron transport region is integrally overlapping the plurality of light emitting regions and the non-light emitting region, and the hole transport region does not overlap at least a portion of the non-light emitting region.

According to some embodiments, the second electrode may integrally overlap the plurality of light emitting regions and the non-light emitting region.

According to some embodiments, the hole transport region may overlap the plurality of light emitting regions.

According to some embodiments, the hole transport region may include a hole injection layer on the first electrode, and a hole transport layer on the hole injection layer.

According to some embodiments, the electron transport region may include
an electron transport layer on the light emitting layer, and an electron injection layer on the electron transport layer.

According to some embodiments, the light emitting layer may cover at least a portion of the pixel-defining film, and the electron transport region may cover a rest portion of the pixel-defining film which is not covered by the light emitting layer.

According to some embodiments, the pixel-defining film may be an inorganic film.

According to some embodiments, an angle between a side surface of the light emitting layer and a plane may be substantially perpendicular to the plane.

According to some embodiments, the display panel may further include a thin-film encapsulation layer on the light emitting element layer and configured to cover the light emitting element layer.

According to some embodiments, the display panel may further include a circuit layer between the base layer and the light emitting element layer.

According to some embodiments of the present disclosure, a manufacturing method of a display panel includes: preparing a preliminary display panel including a first electrode and a pixel-defining film having an opening, which defines a pixel region, by exposing a portion of the first electrode; patterning a light emitting layer and a sacrificial layer on the preliminary display panel to correspond to the pixel region; removing the sacrificial layer; forming an electron transport region on the light emitting layer; and forming a second electrode on the electron transport region, wherein the electron transport region is entirely formed while covering the pixel-defining film and the light emitting layer.

According to some embodiments, the second electrode may be entirely formed while covering the electron transport region.

According to some embodiments, the manufacturing method may further include forming a hole transport region on the preliminary display panel to correspond to the pixel region.

According to some embodiments, the hole transport region may include a hole injection layer and a hole transport layer.

According to some embodiments, the patterning of the light emitting layer and the sacrificial layer may include: thermally depositing the light emitting layer on the preliminary display panel; thermally depositing the sacrificial layer on the light emitting layer; and removing the light emitting layer and the sacrificial layer in a region other than the pixel region through a photoresist process.

According to some embodiments, the patterning of the light emitting layer and the sacrificial layer may be performed in an atmospheric ambient, and the forming of the electron transport region and the forming of the second electrode are respectively performed in a vacuum.

According to some embodiments, the manufacturing method may further include, before the forming of the electron transport region on the light emitting layer, removing moisture through heating and drying.

According to some embodiments, the manufacturing method may further include forming a thin-film encapsulation layer on the second electrode.

According to some embodiments, the electron transport region may include an electron injection layer and an electron transport layer.

According to some embodiments, a side surface of the patterned light emitting layer may be substantially perpendicular to a plane.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain principles of embodiments according to the present disclosure. In the drawings:

FIG. 1 is a combined perspective view of a display device according to some embodiments of the present disclosure;

FIG. 2 is an exploded perspective view of a display device according to some embodiments of the present disclosure;

FIG. 3 is a cross-sectional view of a display device according to some embodiments of the present disclosure;

FIG. 4 is a plan view of a display module according to some embodiments of the present disclosure;

FIG. 5 is an enlarged cross-sectional view of a portion of a display panel according to some embodiments of the present disclosure;

FIGS. 6A to 6D are cross-sectional views of a light emitting element according to some embodiments of the present disclosure;

FIG. 7 is a flowchart illustrating a manufacturing method of a display panel according to some embodiments of the present disclosure; and

FIGS. 8 to 14 are cross-sectional views respectively illustrating steps of a manufacturing method of a display panel according to some embodiments of the present disclosure.

### DETAILED DESCRIPTION

Embodiments according to the present disclosure may be variously modified and have various forms, and therefore aspects of some embodiments will be illustrated in the drawings and described in more detail below. However, it is not intended to limit embodiments according to the present disclosure to a specific disclosed form, and it will be understood that all modifications, equivalents, or substitutes are included within the spirit and technical scope of embodiments according to the present disclosure.

In this specification, it will be understood that when an element (or region, layer, portion, etc.) is referred to as being “on”, “connected to” or “coupled to” another element, it can be directly on/connected to/coupled to the other element, or a third element therebetween may be present.

Meanwhile, in this specification, when an element is referred to as being “directly located on” another layer, film, region, board, etc., there are no intervening layer, film, region, board, etc., present. For example, the wording “directly located” means that an additional member such as an adhesive member, or the like may not be used between two layers or two members.

Like reference numerals or symbols refer to like elements throughout. In addition, in the drawings, the thickness and the ratio and the dimension of an element are exaggerated for effective description of the technical contents.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, a first element, component, region, layer, or section discussed below could be termed a second element, component, region, layer, or section without departing from the teachings of embodiments according to the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless clearly defined herein.

Hereinafter, a display device and a manufacturing method thereof according to some embodiments of the present disclosure will be described in more detail with reference to the accompanying drawings.

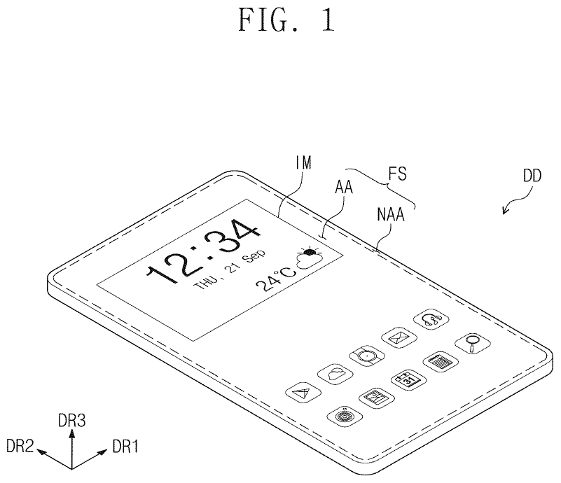

FIG. 1 is a combined perspective view of a display device DD according to some embodiments of the present disclosure.

A display device DD according to some embodiments may be activated in response to an electrical signal. For example, the display device DD may be a mobile phone, a tablet PC, a car navigation system, a game console, or a wearable device, but embodiments according to the present disclosure are not limited thereto. FIG. 1 illustrates that the display device DD is a mobile phone, as an example, but embodiments according to the present disclosure are not limited thereto.

In FIG. 1 and the following drawings, a first direction DR1, a second direction DR2, and a third direction DR3 are illustrated, but the directions indicated by the first to third directions DR1, DR2, and DR3 illustrated in this specification may have a relative concept and may thus be changed to other directions. In addition, directions, which are completely opposite to the directions indicated by the first to third directions DR1, DR2, and DR3, may also be referred to as the first to third directions, and thus denoted as the same reference numerals or symbols.

Referring to FIG. 1, the display device DD according to some embodiments may have a display surface FS defined by the first direction DR1 and the second direction DR2 crossing the first direction DR1. The display device DD may provide an image IM to a user through the display surface FS. The display device DD according to some embodiments may display the image IM, in the third direction DR3, on the display surface FS parallel to each of the first direction DR1 and the second direction DR2. A front surface (or a top surface) and a rear surface (or a bottom surface) of each component may be defined based on a direction in which the image IM is displayed. The front surface and the rear surface may be opposed to each other in the third direction DR3, and the normal directions of the front surface and the rear surface may each be parallel to the third direction DR3.

According to some embodiments, the display surface FS may include an active region AA and a peripheral region NAA adjacent to the active region AA. The peripheral region NAA may be a region in which the image IM is not displayed. However, embodiments according to the present disclosure are not limited thereto, and the peripheral region NAA may be omitted.

The display device DD according to some embodiments may sense an external input applied from the outside. The external input may include various types of inputs provided from the outside of the display device DD. For example, the external input may include not only a touch by a user's body part such as a hand, but also an external input (for example, hovering) applied by being close to the display device DD or by being adjacent by a distance (e.g., a set or predetermined distance) to the display device DD. In addition, the external input may have various types such as physical force, pressure, heat, light, etc.

The display device DD according to some embodiments may further include various electronic modules. For example, an electronic module may include at least one of a camera, a speaker, a light detection sensor, or a heat detection sensor. The electronic module may sense an external subject received through the display surface FS or may provide an audio signal of a voice or the like to the outside through the display surface FS. The electronic module may include a plurality of components, and is not limited to any one embodiment.

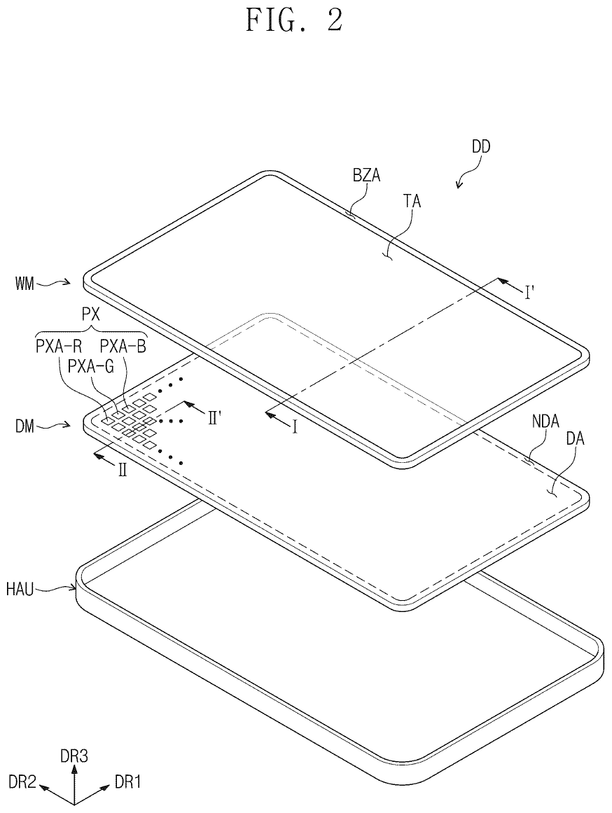

FIG. 2 is an exploded perspective view of a display device DD according to some embodiments of the present disclosure. FIG. 2 illustrates an exploded perspective view of the display device DD according to some embodiments of the present disclosure in FIG. 1.

Referring to FIG. 2, the display device DD according to some embodiments may include a display module DM and a window WM located on the display module DM. The window WM may be located on top of and/or under the display module DM. FIG. 2 illustrates that the window WM is located on top of the display module DM.

In addition, the display device DD according to some embodiments may further include an electronic module located under the display module DM. For example, the electronic module may include a camera module.

In addition, according to some embodiments, the display device DD according to some embodiments may further include an adhesive layer and/or a polarizing film which are/is located between the display module DM and the window WM.

In addition, according to some embodiments, the display device DD according to some embodiments may further include a lower functional layer located under the display module DM. The lower functional layer may be a layer for supporting the display module DM or for preventing or reducing deformation of the display module DM due to an external impact or force. The lower functional layer may include at least one of a cushion layer, a support plate, a shielding layer, a filling layer, or an interlayer bonding layer.

The display device DD according to some embodiments may further include a housing HAU that accommodates the display module DM, the lower functional layer, and the like. The housing HAU may be coupled to the window WM to form an exterior of the display device DD. The housing HAU may include a material having a relatively high rigidity. For example, the housing HAU may include a plurality of frames and/or plates composed of glass, plastic, or metal. The display module DM may be accommodated in an accommodation space or cavity and protected from an external impact.

The display module DM according to some embodiments may display the image IM (see FIG. 1) in response to an electrical signal, and may transmit/receive information about an external input. The display module DM may include a display panel and a sensor layer located on the display panel.

The display module DM may include a display region DA and a non-display region NDA. The display region DA may be a region for providing the image IM (see FIG. 1). Pixels PX may be located in the display region DA. The non-display region NDA may be adjacent to (e.g., in a periphery or outside a footprint of) the display region DA. The non-display region NDA may surround the display region DA. A driving circuit, a driving wire, or the like for driving the display region DA may be located in the non-display region NDA.

The display module DM may include a plurality of pixels PX. The pixels PX may each emit light in response to an electrical signal. The image IM (see FIG. 1) may be achieved by light emitted by the pixels PX. The pixels PX may each include a display element. For example, the display element may be an organic light emitting element, an inorganic light emitting element, an organic-inorganic light emitting element, a micro-LED, a nano LED, a quantum-dot light emitting element, an electrophoretic element, an electrowetting element, or the like.

The pixels PX may include a first-color pixel PXA-R, a second-color pixel PXA-G, and a third-color pixel PXA-B which are spaced apart from each other on a plane (or in a plan view). The first-color pixel PXA-R, the second-color pixel PXA-G, and the third-color pixel PXA-B may be referred to as a red-light emitting region PXA-R, a green-light emitting region PXA-G, and a blue-light emitting region PXA-B, respectively.

In the display device DD according to some embodiments, the light emitting regions PXA-R, PXA-G, and PXA-B may be arranged in a form of a stripe. A plurality of red-light emitting regions PXA-R, a plurality of green-light emitting regions PXA-G, and a plurality of blue-light emitting regions PXA-B may each be arranged along the second direction DR2. Alternatively, the red-light emitting regions PXA-R, the green-light emitting regions PXA-G, and the blue-light emitting regions PXA-B may be alternately arranged in this order along the first direction DR1.

An arrangement form of the light emitting regions PXA-R, PXA-G, and PXA-B is not limited to the arrangement form illustrated in FIG. 2, and an arrangement order of the red-light emitting region PXA-R, the green-light emitting region PXA-G, and the blue-light emitting region PXA-B may be provided in various combinations according to a feature of display quality required in the display device DD. For example, the arrangement form of the light emitting regions PXA-R, PXA-G, and PXA-B may have a pentile (PENTILE®) arrangement form or a diamond (Diamond Pixel™) arrangement form.

In FIG. 2, the light emitting regions PXA-R, PXA-G, and PXA-B are illustrated as having a similar area. However, embodiments according to the present disclosure are not limited thereto, and areas of the light emitting regions PXA-R, PXA-G, and PXA-B may vary depending on wavelength regions of the emitted light. For example, according to some embodiments, an area of the green-light emitting region PXA-G may be smaller than that of the blue-light emitting region PXA-B, but embodiments according to the present disclosure are not limited thereto. The areas of the light emitting regions PXA-R, PXA-G, and PXA-B may mean the areas when viewed on a plane (or in a plan view) defined by the first direction DR1 and the second direction DR2.

The window WM may cover an entire top surface of the display module DM. The window WM may have a shape corresponding to the shape of the display module DM. The window WM may have flexibility which is deformed according to a deformation of folding or bending of the display device DD. The window WM may function to protect the display module DM from an external impact.

The window WM may include a transmission region TA and a bezel region BZA. The transmission region TA may overlap at least a portion of the display region DA of the display module DM. The transmission region TA may be an optically transparent region. For example, the transmission region TA may have a transmittance of about 90% or more with respect to a wavelength of a visible light region. The image IM (see FIG. 1) may be provided to a user through the transmission region TA, and the user may receive information through the image IM (see FIG. 1).

The bezel region BZA may be a region having a lower light transmittance than the transmission region TA. The bezel region BZA may define the shape of the transmission region TA. The bezel region BZA may have a color (e.g., a set or predetermined color). The bezel region BZA may cover the non-display region NDA of the display module DM and prevent or reduce visibility of the non-display region NDA from the outside. However, this is an example, and the bezel region BZA may be omitted in the window WM according to some embodiments.

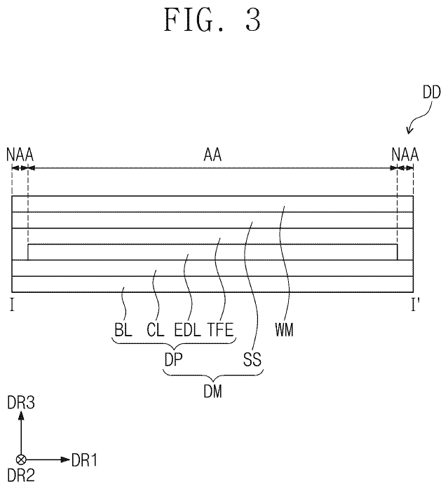

FIG. 3 is a cross-sectional view of a display device DD according to some embodiments of the present disclosure. FIG. 3 is a cross-sectional view taken along the line I-I′ illustrated in FIG. 2.

Referring to FIG. 3, the display device DD may include a display module DM and a window WM located on the display module DM. The display module DM may include a display panel DP.

The display panel DP may include a base layer BL, a circuit layer CL, a light emitting element layer EDL, and an encapsulation layer TFE.

The base layer BL may be a member which provides a base surface on which the circuit layer CL is located. The base layer BL may be a rigid substrate, or a flexible substrate which is capable of bending, folding, rolling, or the like. The base layer BL may be a glass substrate, a metal substrate, a polymer substrate, or the like. However, embodiments according to the present disclosure are not limited thereto, and the base layer BL may be an inorganic layer, an organic layer, or a composite material layer.

The circuit layer CL may be located on the base layer BL. The circuit layer CL may include an insulating layer, a semiconductor pattern, a conductive pattern, a signal line, and the like. An insulating layer, a semiconductor layer, and a conductive layer may be formed on the base layer BL through coating, deposition, or the like, and then the insulating layer, the semiconductor layer, and the conductive layer may be selectively patterned by performing a photolithography process and an etching process multiple times. Then, the semiconductor pattern, the conductive pattern, and the signal line which are included in the circuit layer CL may be formed.

The light emitting element layer EDL may be located on the circuit layer CL. The light emitting element layer EDL may include a light emitting element. For example, the light emitting element may include an organic light emitting material, an inorganic light emitting material, an organic-inorganic light emitting material, quantum dots, quantum rods, a micro-LED, or a nano-LED.

The encapsulation layer TFE may be located on the light emitting element layer EDL. The encapsulation layer TFE may cover the light emitting element layer EDL. The encapsulation layer TFE may be located in the active region AA in which the light emitting element layer EDL is located, and may be located to extend to the peripheral region NAA in which the light emitting element layer EDL is not located. The encapsulation layer TFE may protect the light emitting element layer EDL from moisture, oxygen, and foreign matters such as dust particles.

The display module DM may further include a color filter layer located on the display panel DP. The color filter layer may be formed through a continuous process.

The display module DM may further include a polarizing film located on the display panel DP. The polarizing film may be a film having an optical function for improving light extracting efficiency of the display module DM and reducing the reflectance for external light.

The display module DM may further include a sensor layer SS located on the display panel DP. The sensor layer SS may sense an external input applied from the outside. The external input may be a user's input. The user's input may include various forms of external inputs such as a part of the user's body, light, heat, a pen, pressure, etc.

The window WM may be located on the display module DM. The window WM may allow an image from the display module DM to be transmitted therethrough and may also mitigate an external impact. Accordingly, the window WM may prevent or reduce damage to, or malfunctioning of, the display module DM due to an external impact.

The window WM may cover an entire top surface of the display module DM. The window WM may have a shape corresponding to the shape of the display module DM. The window WM may have flexibility which is deformed according to a deformation of folding or bending of the display device DD.

The window WM may include a glass substrate or a synthetic resin film. The window WM may have a multi-layered structure or a single layered structure. The window WM may further include a window protective layer located on the glass substrate or the synthetic resin film. The window protective layer may include a flexible plastic material such as polyimide or polyethylene terephthalate. In addition, an adhesive layer located between the window and the window protective layer may further be included.

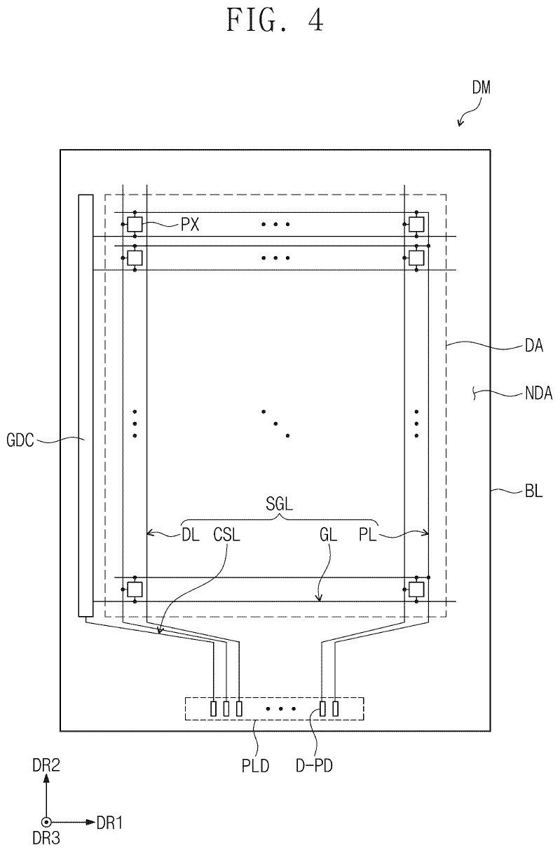

FIG. 4 is a plan view of a display module DM according to some embodiments of the present disclosure.

A display module DM may include a base layer BL which is divided into a display region DA and a non-display region NDA.

The display module DM may include pixels PX located in the display region DA and signal lines SGL electrically connected to the pixels PX. The display module DM may include a driving circuit GDC and a pad part PLD which are located in the non-display region NDA.

The pixels PX may be arranged in the first direction DR1 and in the second direction DR2. The pixels PX may include a plurality of pixel rows which extend in the first direction DR1 and are arranged in the second direction DR2, and a plurality of pixel columns which extend in the second direction DR2 and are arranged in the first direction DR1.

The signal lines SGL may include gate lines GL, data lines DL, a power supply line PL, and a control signal line CSL. The gate lines GL may be connected respectively to corresponding pixels among the pixels PX, and the data lines DL may be connected respectively to corresponding pixels among the pixels PX. The power supply line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate gate signals, and may output the generated gate signals to the gate lines GL in order. The gate driving circuit may further output another control signal to a pixel driving circuit.

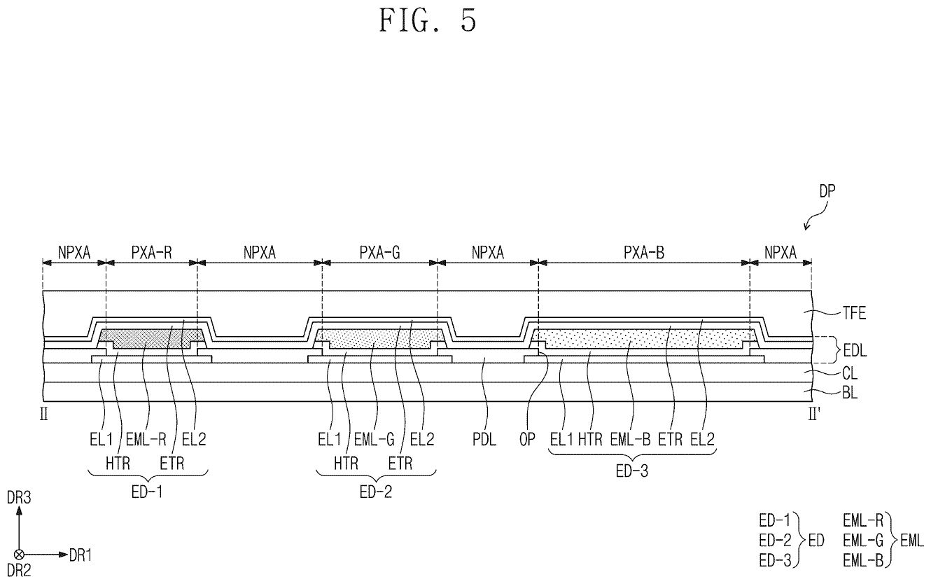

The pad part PLD may be a part to which a flexible printed circuit board is connected. The pad part PLD may include pixel pads D-PD, and the pixel pads D-PD may be pads for connecting the flexible printed circuit board to the display panel DP (see FIG. 5). The pixel pads D-PD may be connected respectively to corresponding signal lines among the signal lines SGL. The pixel pads D-PD may be connected to corresponding pixels PX through the signal lines SGL. In addition, any one pixel pad among the pixel pads D-PD may be connected to the driving circuit GDC.

FIG. 5 is an enlarged cross-sectional view of a portion of a display panel DP according to some embodiments of the present disclosure. FIG. 5 illustrates a cross-section taken along the line II-II′ illustrated in FIG. 2. FIG. 2 illustrates that the light emitting regions PXA-R, PXA-G, and PXA-B have the same length in the first direction DR1, whereas FIG. 5 illustrates that the light emitting regions PXA-R, PXA-G, and PXA-B have different lengths.

Referring to FIG. 5, a display panel DP may include a non-light emitting region NPXA and light emitting regions PXA-R, PXA-G, and PXA-B. The light emitting regions PXA-R, PXA-G, and PXA-B may respectively emit light generated from light emitting elements ED-1, ED-2, and ED-3. The light emitting regions PXA-R, PXA-G, and PXA-B may be arranged to be spaced apart from each other on a plane (or in a plan view).

Each of the light emitting regions PXA-R, PXA-G, and PXA-B may be separated by a pixel-defining film PDL. The non-light emitting region NPXA may be regions between the neighboring light emitting regions PXA-R, PXA-G, and PXA-B, and may correspond to the pixel-defining film PDL. On a plane (or in a plan view), the non-light emitting region NPXA may surround the light emitting regions PXA-R, PXA-G, and PXA-B. However, in this specification, the light emitting regions PXA-R, PXA-G, and PXA-B may each correspond to the pixel PX (see FIG. 2). The pixel-defining film PDL may separate the light emitting elements ED-1, ED-2, and ED-3. Light emitting layers EML-R, EML-G, and EML-B of the light emitting elements ED-1, ED-2, and ED-3 may be separated by being located in openings OP that are defined in the pixel-defining film PDL.

The light emitting regions PXA-R, PXA-G, and PXA-B may be classified into a plurality of groups depending on colors of light generated from the light emitting elements ED-1, ED-2, and ED-3. FIG. 5 illustrates three light emitting regions PXA-R, PXA-G, and PXA-B which emit red light, green light, and blue light. For example, the display panel DP according to some embodiments may include a red-light emitting region PXA-R, a green-light emitting region PXA-G, a blue-light emitting region PXA-B which are separated from each other. The red-light emitting region PXA-R may be referred to as a first light emitting region, the green-light emitting region PXA-G may be referred to as a second light emitting region, and the blue-light emitting region PXA-B may be referred to as a third light emitting region.

The plurality of light emitting elements ED-1, ED-2, and ED-3 in the display panel DP may emit light in wavelength ranges which are different from each other. For example, according to some embodiments, the display panel DP may include a first light emitting element ED-1 which emits red light, a second light emitting element ED-2 which emits green light, and a third light emitting element ED-3 which emits blue light. That is, the red-light emitting region PXA-R, the green-light emitting region PXA-G, and the blue-light emitting region PXA-B of the display panel DP may respectively correspond to a first-color light emitting element ED-1, a second-color light emitting element ED-2, and a third-color light emitting element ED-3.

However, embodiments according to the present disclosure are not limited thereto, and the first- to third-color light emitting elements ED-1, ED-2, and ED-3 may emit light in the same wavelength range or at least one thereof may emit light in a wavelength range which is different from the others. For example, the first- to third-color light emitting elements ED-1, ED-2, and ED-3 may all emit blue light.

The light emitting element layer EDL may include the first- to third-color light emitting elements ED-1, ED-2, and ED-3, and the pixel-defining film PDL. The light emitting elements ED-1, ED-2, and ED-3 may each include a first electrode EL1 and a second electrode EL2, and may respectively include the light emitting layers EML-R, EML-G, and EML-B which are located between the first electrode EL1 and the second electrode EL2. The light emitting element layer EDL may include the pixel-defining film PDL which is located between pixel regions PXA-R, PXA-G, and PXA-B to define the pixel regions PXA-R, PXA-G, and PXA-B. The light emitting element layer EDL may further include a hole transport region HTR located between the first electrode EL1 and each of the light emitting layers EML-R, EML-G, and EML-B. The light emitting element layer EDL may further include an electron transport region ETR located between the second electrode EL2 and each of the light emitting layers EML-R, EML-G, and EML-B.

The first electrode EL1 may be located on the circuit layer CL. The first electrode EL1 may be arranged to correspond to the light emitting regions PXA-R, PXA-G, and PXA-B. The first electrode EL1 may be arranged to be spaced apart from each other, on a plane (or in a plan view), corresponding to the light emitting regions PXA-R, PXA-G, and PXA-B. A portion of the first electrode EL1 may be covered by the pixel-defining film PDL. For example, a portion of the first electrode EL1 adjacent to the non-light emitting region NPXA may be covered by the pixel-defining film PDL. Portions, of a top surface of the first electrode EL1, which overlap the light emitting regions PXA-R, PXA-G, and PXA-B, may be exposed by the openings OP defined in the pixel-defining film PDL.

The first electrode EL1 may have electrical conductivity. The first electrode EL1 may be formed of a metal material, a metal alloy, or a conductive compound. The first electrode EL1 may be an anode or a cathode. However, embodiments according to the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, or Zn, two or more compounds selected from thereamong, two or more mixtures selected from thereamong, or an oxide thereof.

When the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), or the like. When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, or a compound or mixture thereof (e.g., mixture of Ag and Mg). Alternatively, the first electrode EL1 may have a multi-layered structure including a reflective film or a transflective film formed of the above-described materials and a transparent conductive film formed of indium tin oxide (ITO), indium zinc oxide (IZO), zinc oxide (ZnO), indium tin zinc oxide (ITZO), or the like. For example, the first electrode EL1 may have a three-layered structure of ITO/Ag/ITO, but embodiments are not limited thereto. In addition, embodiments according to the present disclosure are not limited thereto, and the first electrode EL1 may include the aforementioned metal material, a combination of two or more metal materials selected from among the aforementioned metal materials, an oxide of the aforementioned metal materials, or the like.

The pixel-defining film PDL may be located on the circuit layer CL. The pixel-defining film PDL may be arranged to correspond to the non-light emitting region NPXA. The openings OP corresponding to the light emitting regions PXA-R, PXA-G, and PXA-B may be defined in the pixel-defining film PDL. The pixel-defining film PDL may cover a portion of the first electrode EL1. The top surface of the first electrode EL1 may be exposed by the opening OP that is defined in the pixel-defining film PDL. The pixel-defining film PDL may be an inorganic film. For example, the pixel-defining film PDL may include silicon oxide (SiOₓ) and/or silicon nitride (SiN_{y}). Because the pixel-defining film PDL is an inorganic film, a defect due to short-circuiting between the first electrode EL1 and the second electrode EL2 may not occur.

The hole transport regions HTR may be provided on the first electrode EL1. The hole transport regions HTR may be located within the openings OP defined in the pixel-defining film PDL. The hole transport regions HTR may be arranged to be spaced apart from each other, on a plane (or in a plan view), corresponding to the light emitting regions PXA-R, PXA-G, and PXA-B. Because the hole transport regions HTR are arranged to be spaced apart from each other, a current leakage between the pixels may be prevented or reduced. In addition, the hole transport regions HTR may cover a portion of the pixel-defining film PDL adjacent to the openings OP. However, unlike what is illustrated in FIG. 5, the hole transport regions HTR may be located only in the openings OP without covering a portion of the pixel-defining film PDL.

The light emitting layer EML may be located on the hole transport region HTR. For example, as illustrated in FIG. 5, the first-color light emitting layer EML-R may be located in the first-color light emitting element ED-1, the second-color light emitting layer EML-G may be located in the second-color light emitting element ED-2, and the third-color light emitting layer EML-B may be located in the third-color light emitting element ED-3. The first-color light emitting layer EML-R may emit red light, the second-color light emitting layer EML-G may emit green light, and the third-color light emitting layer EML-B may emit blue light.

The light emitting layers EML-R, EML-G, and EML-B may further protrude, in the third direction DR3, toward an encapsulation layer TFE than the pixel-defining film PDL. The portion of the pixel-defining film PDL adjacent to the light emitting regions PXA-R, PXA-G, and PXA-B may be covered by the light emitting layer EML. Side surfaces of the light emitting layers EML-R, EML-G, and EML-B may be covered by the electron transport regions ETR. Angles between a plane and the side surfaces of the light emitting layers EML-R, EML-G, and EML-B may be perpendicular (or substantially perpendicular) to the plane. Here, the side surfaces may mean surfaces, of the light emitting layers EML-R, EML-G, and EML-B, parallel (or substantially parallel) to the third direction DR3, and the plane may mean a surface defined by the first direction DR1 and the second direction DR2. The wording “being substantially perpendicular” may mean that the angle is equal to or more than about 80° and equal to or less than about 100°.

The light emitting layers EML-R, EML-G, and EML-B may be arranged to be spaced apart from each other, on a plane (or in a plan view), corresponding to the light emitting regions PXA-R, PXA-G, and PXA-B. The first light emitting layer EML-R may be located in the first light emitting region PXA-R, the second light emitting layer EML-G may be located in the second light emitting region PXA-G, and the third light emitting layer EML-B may be located in the third light emitting region PXA-B. The first light emitting layer EML-R may be referred to as a red-light emitting region, the second light emitting layer EML-G may be referred to as a green-light emitting region, and the third light emitting layer EML-B may be referred to as a blue-light emitting region.

The electron transport region ETR may be located on the light emitting layer EML. The electron transport region ETR may integrally overlap the light emitting regions PXA-R, PXA-G, and PXA-B and the non-light emitting region NPXA. For example, the electron transport region ETR may cover the first to third light emitting layers EML-R, EML-G, and EML-B, and the pixel-defining film PDL which is not covered by the light emitting layer EML and exposed. That is, the electron transport region ETR may be formed as a common layer. Because the electron transport regions ETR are not spaced apart from each other by being patterned in the respective light emitting regions PXA-R, PXA-G, and PXA-B, but the electron transport region ETR is formed as a common layer, the electron transport region ETR may not be exposed to moisture/oxygen, so that moisture permeation and oxidation may be prevented or reduced.

The electron transport region ETR may be formed using various methods such as a vacuum deposition method, a spin coating method, a cast method, a Langmuir-Blodgett (LB) method, an inkjet printing method, a laser printing method, a laser induced thermal imaging (LITI) method, or the like.

The second electrode EL2 may be provided on the electron transport region ETR. The second electrode EL2 may integrally overlap the light emitting regions PXA-R, PXA-G, and PXA-B and the non-light emitting region NPXA. For example, the second electrode EL2 may be formed as a common layer. Because the second electrodes EL2 are not spaced apart from each other by being patterned in the respective light emitting regions PXA-R, PXA-G, and PXA-B, but the second electrode EL2 is formed as a common layer, the second electrode EL2 may not be exposed to moisture/oxygen, so that moisture permeation and oxidation may be prevented or reduced.

The second electrode EL2 may be a common electrode. The second electrode EL2 may be a cathode or an anode, but embodiments according to the present disclosure are not limited thereto. For example, when the first electrode EL1 is an anode, the second electrode EL2 may be a cathode, and when the first electrode EL1 is a cathode, the second electrode EL2 may be an anode. The second electrode EL2 may be a transmissive electrode, a transflective electrode, or a reflective electrode. The second electrode EL2 may include at least one selected from among Ag, Mg, Cu, Al, Pt, Pd, Au, Ni, Nd, Ir, Cr, Li, Ca, LiF, Mo, Ti, W, In, Sn, or Zn, two or more compounds selected from thereamong, two or more mixtures selected from thereamong, or an oxide thereof.

When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), or the like. When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, or a compound or mixture thereof (e.g., mixture of Ag and Mg). Alternatively, the second electrode EL2 may have a multi-layered structure including a reflective film or a transflective film formed of the above-described materials and a transparent conductive film formed of indium tin oxide (ITO), indium zinc oxide (IZO), zinc oxide (ZnO), indium tin zinc oxide (ITZO), or the like. Embodiments according to the present disclosure are not limited thereto, and the second electrode EL2 may include the aforementioned metal material, a combination of two or more metal materials selected from among the aforementioned metal materials, an oxide of the aforementioned metal materials, or the like.

The encapsulation layer TFE may be located on the second electrode EL2. The encapsulation layer TFE may cover steps formed by the light emitting elements ED-1, ED-2, and ED-3 and may provide a flat surface. The encapsulation layer TFE may cover the light emitting elements ED-1, ED-2, and ED-3. The encapsulation layer TFE may seal the light emitting element layer EDL. The encapsulation layer TFE may be a thin-film encapsulation layer. The encapsulation layer TFE may be a single layer, or a multi-layer in which a plurality of layers are stacked. The encapsulation layer TFE may include at least one insulating layer. The encapsulation layer TFE according to some embodiments may include at least one inorganic film (hereinafter, an inorganic encapsulation film). In addition, the encapsulation layer TFE according to some embodiments may include at least one organic film (hereinafter, an organic encapsulation film) and at least one inorganic encapsulation film.

The inorganic encapsulation film may protect the light emitting element layer EDL from moisture/oxygen, and the organic encapsulation film may protect the light emitting element layer EDL from foreign matters such as dust particles. The inorganic encapsulation film may include silicon nitride, silicon oxynitride, silicon oxide, titanium oxide, aluminum oxide, or the like, but is not particularly limited thereto. The organic encapsulation film may include an acrylic compound, an epoxy-based compound, or the like. The organic encapsulation film may include a photopolymerizable organic material, but is not particularly limited.

The encapsulation layer TFE according to some embodiments may include a first inorganic layer located on the light emitting element layer EDL, an organic layer located on the first inorganic layer, and a second inorganic layer located on the organic layer.

According to some embodiments, the first inorganic layer may be directly located on the light emitting element layer EDL. For example, the first inorganic layer may be directly located on the second electrode EL2. Alternatively, when a capping layer CPL is located on the second electrode EL2, the first inorganic layer may be directly located on the capping layer CPL. The first inorganic layer may be located on the second electrode EL2 to protect the light emitting element layer EDL from moisture/oxygen.

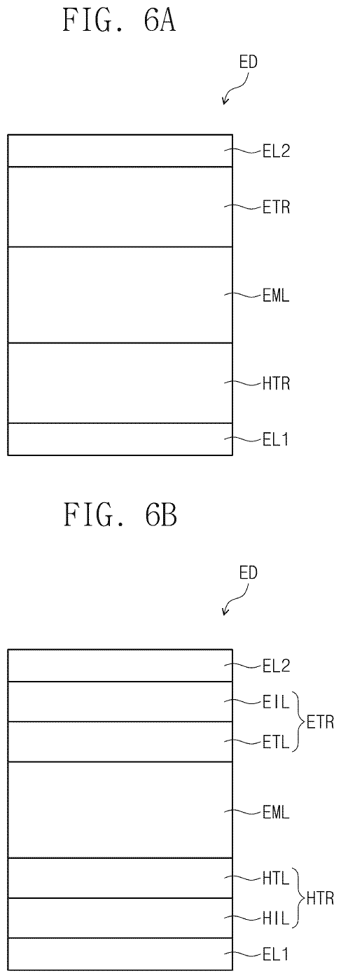

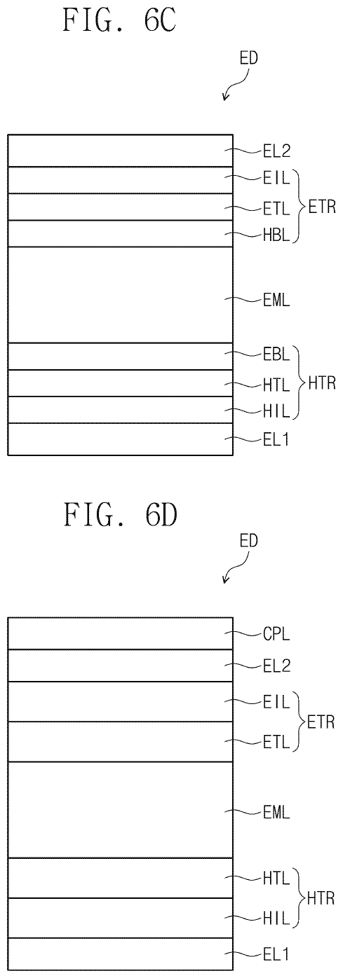

FIGS. 6A to 6D are cross-sectional views of a light emitting element ED according to some embodiments of the present disclosure. FIGS. 6A to 6D each illustrate the cross-section of a light emitting element ED on behalf of the first- to third-color light emitting elements ED-1, ED-2, and ED-3.

Referring to FIG. 6B, a hole transport region HTR may include a hole injection layer HIL and a hole transport layer HTL. Referring to FIG. 60, the hole transport region HTR may further include an electron blocking layer EBL.

The hole transport region HTR may have a single layer composed of a single material, a single layer composed of a plurality of different materials, or a multi-layered structure having multiple layers composed of a plurality of different materials. For example, the hole transport region HTR may have a single layer structure of the hole injection layer HIL or the hole transport layer HTL, and may have a single layer structure composed of a hole injection material and a hole transport material. Alternatively, the hole transport region HTR may have a single layer structure composed of a plurality of different materials, or may have a structure in which the hole injection layer HIL/the hole transport layer HTL, the hole injection layer HIL/the hole transport layer HTL/a buffer layer, the hole injection layer HIL/the buffer layer/the hole transport layer HTL/the buffer layer, or the hole injection layer HIL/the hole transport layer HTL/the electron blocking layer EBL are sequentially stacked from a first electrode EL1, but embodiments according to the present disclosure are not limited thereto.

Referring to FIG. 6A, an electron transport region ETR may be located on a light emitting layer EML. Referring to FIG. 6B, the electron transport region ETR may include an electron injection layer EIL and an electron transport layer ETL. Referring to FIG. 6C, the electron transport region ETR may further include a hole blocking layer HBL.

Referring to FIGS. 6A to 6D together, the electron transport region ETR may have a single layer composed of a single material, a single layer composed of a plurality of different materials, or a multi-layered structure having multiple layers composed of a plurality of different materials. For example, the electron transport region ETR may have a single layer structure of the electron injection layer EIL or the electron transport layer ETL, and may have a single layer structure composed of an electron injection material and an electron transport material. Alternatively, the electron transport region ETR may have a single layer structure composed of a plurality of different materials or a structure in which the electron transport layer ETL/the electron injection layer EIL, the hole blocking layer HBL/the electron transport layer ETL/the electron injection layer EIL are sequentially stacked from the light emitting layer EML but is not limited thereto.

The capping layer CPL (see FIG. 6D) may further be located on a second electrode EL2 of the light emitting element ED according to some embodiments. The capping layer CPL may be multiple layers or a single layer. According to some embodiments, the capping layer CPL may be an organic layer or an inorganic layer. For example, when the capping layer CPL includes an inorganic material, the inorganic material may include an alkali metal compound such as LiF, an alkaline earth metal compound such as MgF₂, etc., SiON, SiNₓ, and SiO_{y}.

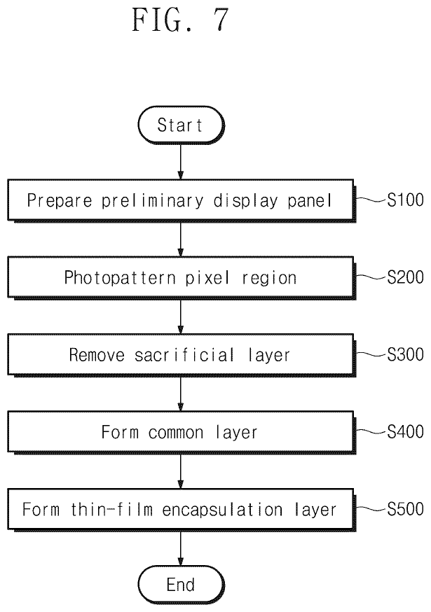

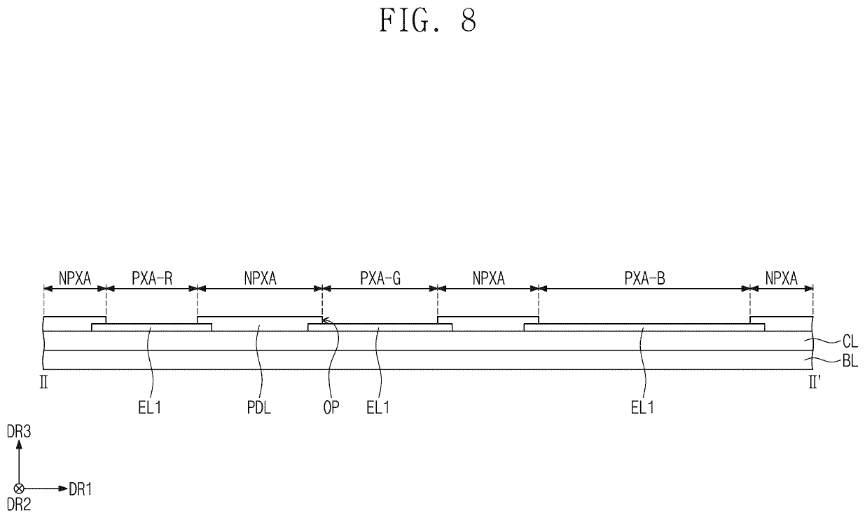

FIG. 7 is a flowchart illustrating a manufacturing method of the display panel DP (see FIG. 5) according to some embodiments of the present disclosure. FIGS. 8 to 14 are cross-sectional views respectively illustrating steps of the manufacturing method of the display panel DP (see FIG. 5) according to some embodiments of the present disclosure.

Referring to FIG. 7, a manufacturing method of a display panel according to some embodiments of the present disclosure may include: a step of preparing a preliminary display panel (S100), a step of patterning in a pixel region (S200), a step of removing a sacrificial layer (S300), and a step of forming a common layer (S400). The manufacturing method of the display panel according to some embodiments of the present disclosure may further include a step of forming a thin-film encapsulation layer (S500).

FIG. 8 is a cross-sectional view illustrating the step of preparing a preliminary display panel (S100). The preliminary display panel may include a base layer BL, a circuit layer CL located on the base layer BL, a first electrode EL1 located on the circuit layer CL, and a pixel-defining film PDL located on the circuit layer CL.

The aforementioned description made with reference to FIGS. 3 to 5 may be similarly applied to the base layer BL, the circuit layer CL, the first electrode EL1, and the pixel-defining film PDL. The first electrode EL1 may be formed in pixel regions PXA-R, PXA-G, and PXA-B, for example, through a sputtering process. The pixel-defining film PDL may be formed, for example, through chemical vapor deposition (CVD). The pixel-defining film PDL may be an inorganic film. Because the pixel-defining film PDL is the inorganic film, the pixel-defining film PDL may be maintained without being removed during a dry etching of a patterning step to be described later.

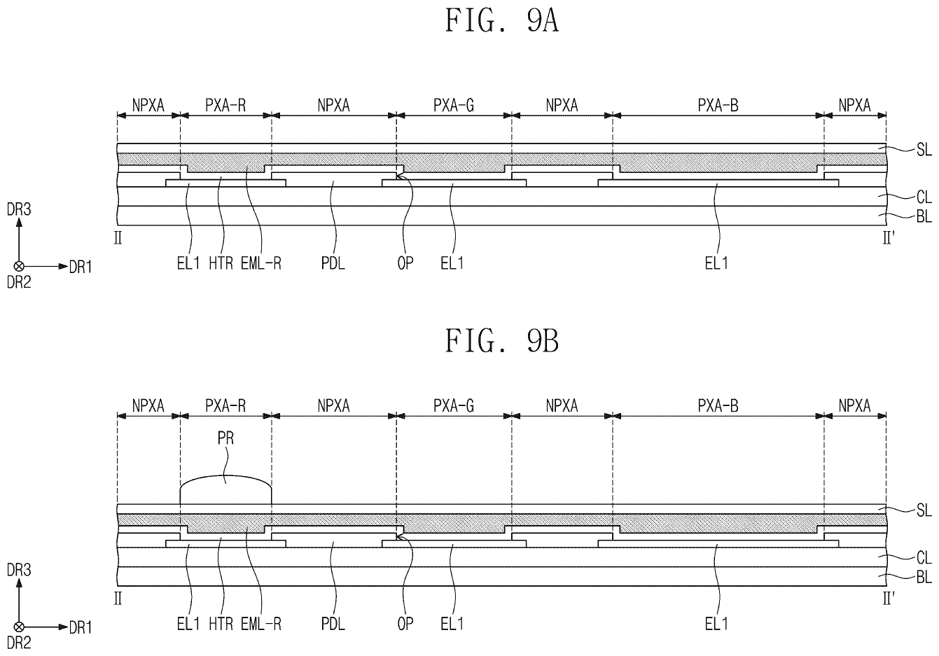

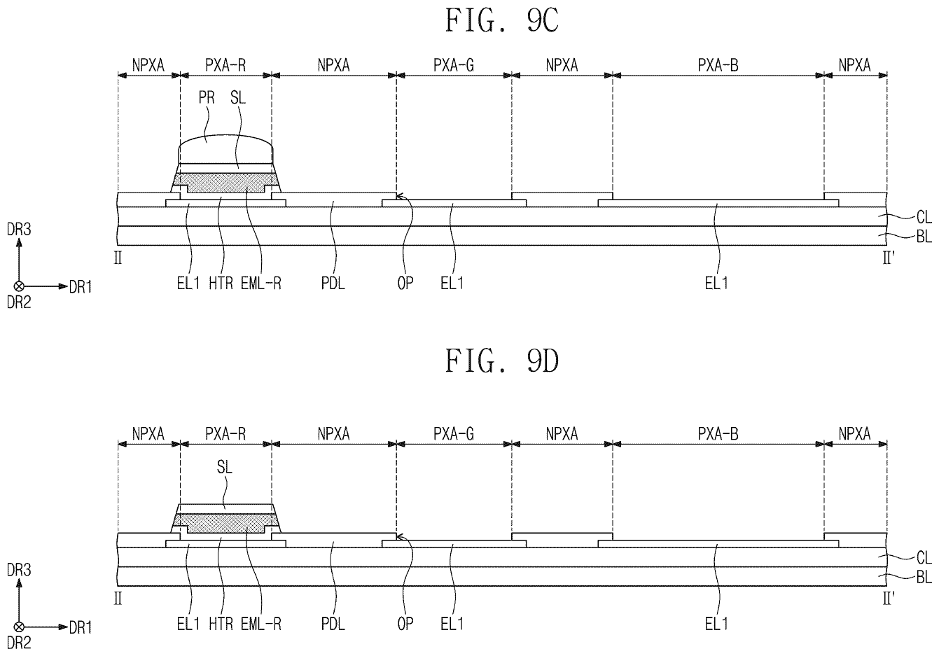

FIGS. 9A to 11 are cross-sectional views illustrating the step of patterning in a pixel region (S200). The step of patterning in the pixel region (S200) may be a step of patterning light emitting layers EML-R, EML-G, and EML-B and a sacrificial layer SL, corresponding to pixel regions PXA-R, PXA-G, and PXA-B.

FIGS. 9A to 9D each illustrate the step of patterning a first light emitting layer EML-R and the sacrificial layer SL in a first pixel region PXA-R. The step of patterning the first light emitting layer EML-R and the sacrificial layer SL in the first pixel region PXA-R may include a step of patterning a hole transport region HTR.

Referring to FIG. 9A, the hole transport region HTR, the first light emitting layer EML-R, and the sacrificial layer SL may be entirely formed. For example, the hole transport region HTR, the first light emitting layer EML-R, and the sacrificial layer SL may be formed through a thermal evaporation process. The sacrificial layer SL may be an inorganic film, an organic film, or metal.

Referring to FIG. 9B, a photoresist PR may be formed corresponding to the first pixel region PXA-R. A material which does not affect underlying organic layers (light emitting layer, or the like) may be used for the photoresist PR.

Referring to FIG. 9C, organic layers formed in a region other than the first pixel region PXA-R may be removed through dry etching in a state in which the photoresist PR is formed in the first pixel region PXA-R.

Referring to FIG. 9D, when the photoresist PR is removed, the patterning of the hole transport region HTR, the first light emitting layer EML-R, and the sacrificial layer SL in the first pixel region PXA-R may be completed.

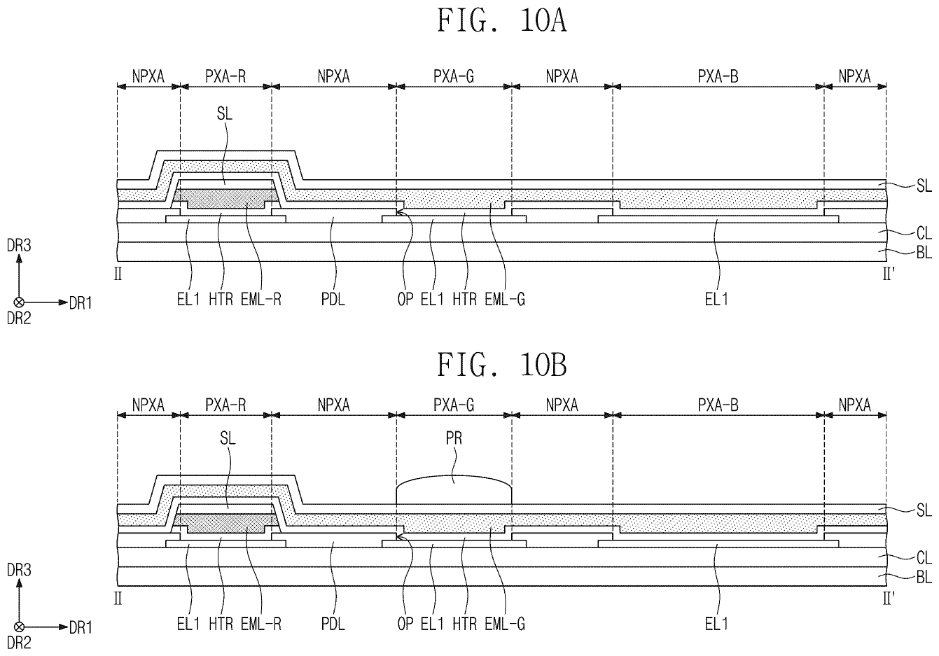

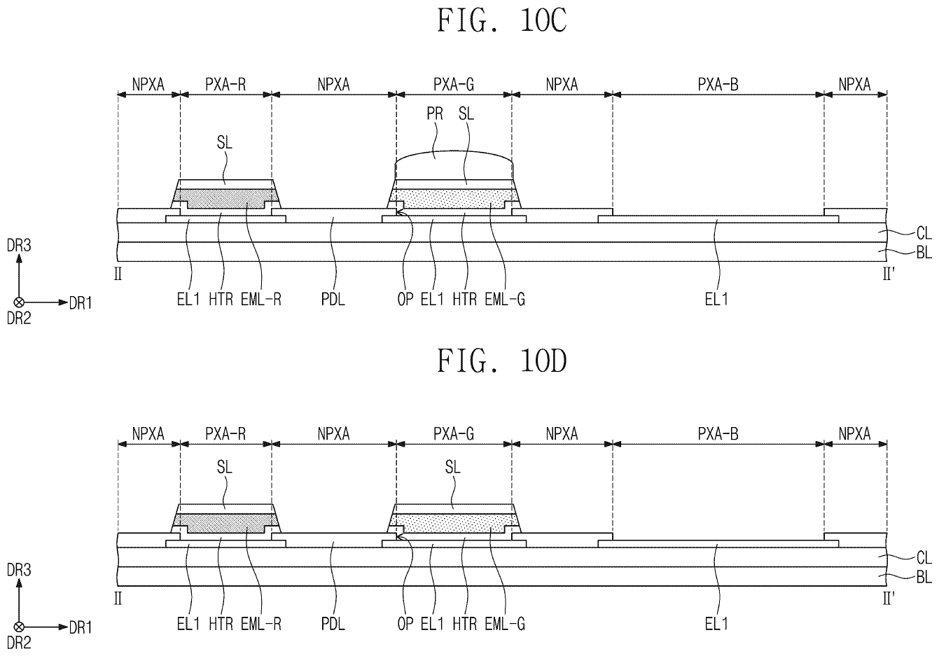

FIGS. 10A to 10D each illustrate the step of patterning a second light emitting layer EML-G and the sacrificial layer SL in a second pixel region PXA-G. The step of patterning the second light emitting layer EML-G and the sacrificial layer SL in the second pixel region PXA-G may include a step of patterning a hole transport region HTR.

Referring to FIG. 10A, the hole transport region HTR, the second light emitting layer EML-G, and the sacrificial layer SL may be entirely formed. For example, the hole transport region HTR, the second light emitting layer EML-G, and the sacrificial layer SL may be formed through a thermal evaporation process. The sacrificial layer SL may be an inorganic film, an organic film, or metal.

Referring to FIG. 10B, a photoresist PR may be formed corresponding to the second pixel region PXA-G. A material which does not affect underlying organic layers (light emitting layer, or the like) may be used for the photoresist PR.

Referring to FIG. 10C, organic layers formed in a region other than the second pixel region PXA-G may be removed through dry etching in a state in which the photoresist PR is formed in the second pixel region PXA-G.

Referring to FIG. 10D, when the photoresist PR is removed, the patterning of the hole transport region HTR, the second light emitting layer EML-G, and the sacrificial layer SL in the second pixel region PXA-G may be completed.

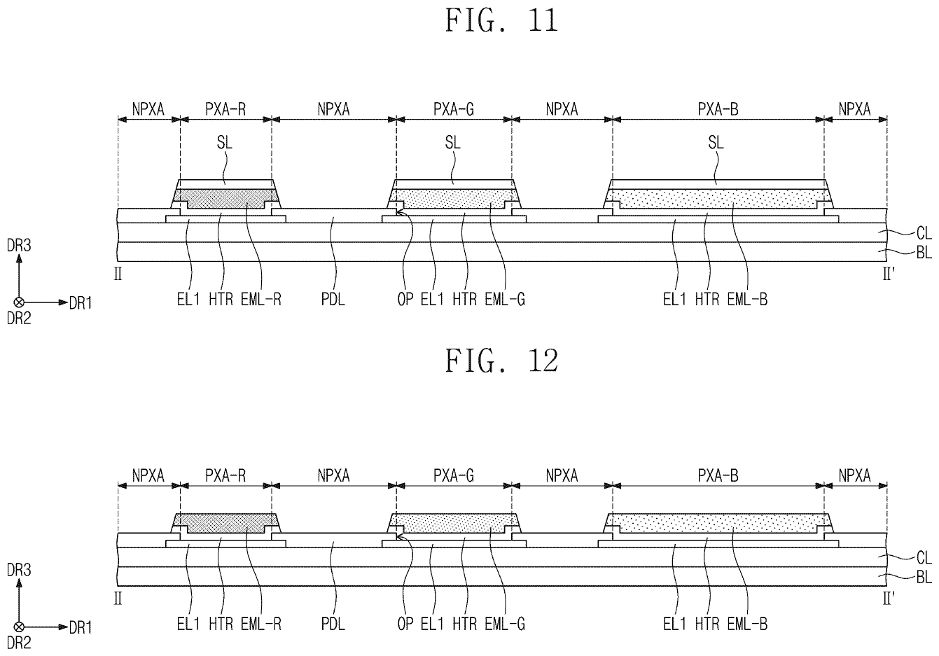

FIG. 11 illustrates the step of patterning a third light emitting layer EML-B and the sacrificial layer SL in a third pixel region PXA-B. The step of patterning the third light emitting layer EML-B and the sacrificial layer SL in the third pixel region PXA-B may include a step of patterning a hole transport region HTR. The hole transport region HTR, the third light emitting layer EML-B, and the sacrificial layer SL may be entirely formed, and a photoresist PR may be formed corresponding to the third pixel region PXA-B. Then, organic layers formed in a region other than the third pixel region PXA-B may be removed through dry etching. When the photoresist PR is removed, the patterning of the hole transport region HTR, the third light emitting layer EML-B, and the sacrificial layer SL in the third pixel region PXA-B may be completed.

FIG. 12 is a cross-sectional view illustrating the step of removing the sacrificial layer SL (S300). The sacrificial layer SL may be removed through wet etching so that underlying organic layers are not damaged. The sacrificial layer SL may protect underlying light emitting layers EML-R, EML-G, and EML-B until the process step before the sacrificial layer SL is removed.

Angles between a plane and side surfaces of the light emitting layers EML-R, EML-G, and EML-B, which are formed through a photopatterning process, may be perpendicular (or substantially perpendicular) to the plane. Here, the side surfaces may mean surfaces, of the light emitting layers EML-R, EML-G, and EML-B, parallel (or substantially parallel) to the third direction DR3, and the plane may mean a surface defined by the first direction DR1 and the second direction DR2. The wording “being substantially perpendicular” may mean that the angle is equal to or more than about 80° and equal to or less than about 100°. Unlike embodiments according to the present disclosure, when the light emitting layers are formed through a fine metal mask process, an angle of a side surface of a light emitting layer with respect to a plane may become smaller due to a shadow effect. In the manufacturing method of the display panel according to some embodiments of the present disclosure, the light emitting layers EML-R, EML-G, and EML-B are formed through the photopatterning process, and therefore a display panel, even if the panel is a large panel, may be manufactured as a single panel regardless of a size of the panel.

The process steps described above with reference to FIGS. 8 to 12 may be performed in an atmospheric ambient. The process steps in FIG. 13 and below may be performed in a vacuum. The manufacturing method of the display panel according to some embodiments of the present disclosure may further include a step of removing moisture from a substrate by heating and drying the substrate in a state of FIG. 12 before forming a common layer in FIG. 13. For example, the substrate in the state of FIG. 12 may be dried at a temperature of about 90° or less so that organic matters are not damaged.

FIG. 13 is a cross-sectional view illustrating the step of forming a common layer (S400). The step of forming the common layer (S400) may include a step of forming an electron transport region ETR on light emitting layers EML-R, EML-G, and EML-B, and a step of forming a second electrode EL2 on the electron transport region ETR. The electron transport region ETR may be entirely formed while covering the light emitting layers EML-R, EML-G, and EML-B, and a pixel-defining film PDL which is not covered by the light emitting layers EML-R, EML-G, and EML-B and exposed. The electron transport region ETR may be formed, for example, through a thermal deposition process. The second electrode EL2 may be entirely formed while covering the electron transport region ETR.

Because the electron transport region ETR and the second electrode EL2 are not spaced apart from each other by being patterned in each of pixel regions PXA-R, PXA-G, and PXA-B, but formed as common layers, the electron transport region ETR and the second electrode EL2 may not be exposed to moisture/oxygen, so that moisture permeation and oxidation may be prevented or reduced.

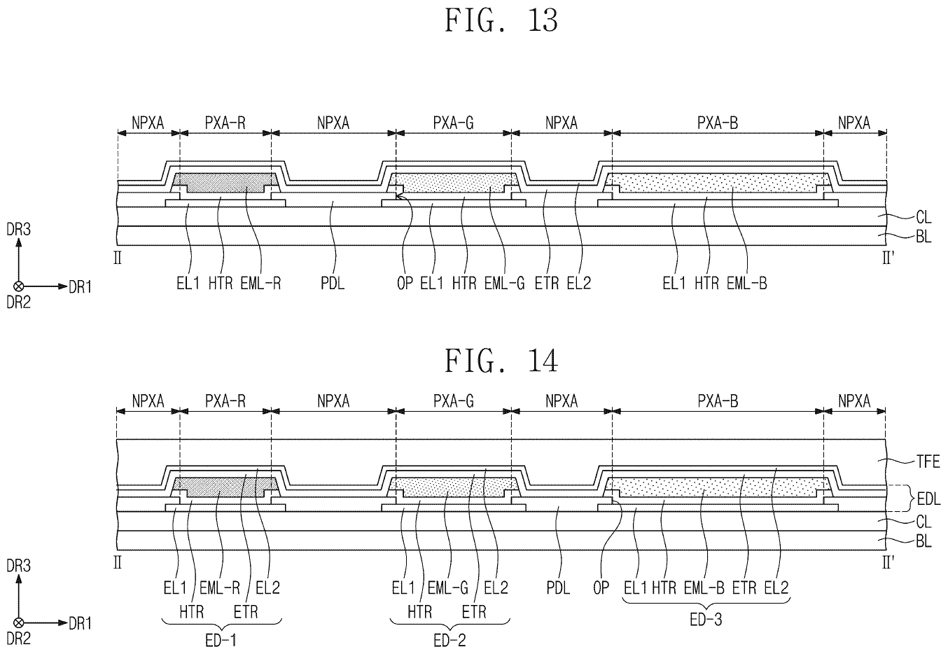

FIG. 14 is a cross-sectional view illustrating the step of forming a thin-film encapsulation layer (S500). The encapsulation layer TFE may be entirely formed while covering the second electrode EL2. The encapsulation layer TFE may include at least one inorganic film and at least one organic film, and the aforementioned description made with reference to FIGS. 3 to 5 may be similarly applied to the encapsulation layer TFE.

In the manufacturing method of a display panel according to some embodiments of the present disclosure, a light emitting layer, or the like is patterned through a photopatterning process, whereby a separate fine metal mask may be unnecessary, a high-resolution panel may be manufactured, and even a large-sized panel may be manufactured as a single panel. In addition, in the manufacturing method of a display panel according to some embodiments of the present disclosure, an electron transport region and a second electrode may each be formed as a common layer in a vacuum so as not be exposed to atmosphere, so that moisture permeation and oxidation may be prevented or reduced. Thus, the reliability of a display panel thus manufactured may be improved.

According to the above description, a display panel and a manufacturing method thereof according to some embodiments of the present disclosure may prevent or reduce moisture permeation and oxidation of layers on top of the light emitting layer by providing the layers on top of the light emitting layer as common layers so as not to be exposed to atmosphere during process steps.

In the above, description has been made with reference to some embodiments of the present disclosure, but those skilled in the art or those of ordinary skill in the relevant technical field may understand that various modifications and changes may be made to the present disclosure within the scope not departing from the spirit and the technology scope of the present disclosure described in the claims to be described later. Therefore, the technical scope of embodiments according to the present disclosure are not limited to the contents described in the detailed description of the specification, but should be determined by the appended claims, and their equivalents.

What is claimed is:

1. A display panel comprising:
a base layer; and
a light emitting element layer on the base layer, and including a plurality of light emitting regions spaced apart from each other in a plan view and a non-light emitting region surrounding each of the plurality of light emitting regions,
wherein the light emitting element layer includes:
a first electrode on the base layer to correspond to the plurality of light emitting regions;
a pixel-defining film, in which openings corresponding to the plurality of light emitting regions are defined, and which is on the base layer;
a hole transport region on the first electrode;
a light emitting layer on the hole transport region to correspond to the plurality of light emitting regions;
an electron transport region on the light emitting layer; and
a second electrode on the electron transport region,
the electron transport region integrally overlaps the plurality of light emitting regions and the non-light emitting region, and
the hole transport region does not overlap at least a portion of the non-light emitting region.

2. The display panel of claim 1, wherein the second electrode integrally overlaps the plurality of light emitting regions and the non-light emitting region.

3. The display panel of claim 1, wherein the hole transport region overlaps the plurality of light emitting regions.

4. The display panel of claim 1, wherein the hole transport region comprises a hole injection layer on the first electrode, and a hole transport layer on the hole injection layer.

5. The display panel of claim 1, wherein the electron transport region comprises an electron transport layer on the light emitting layer, and an electron injection layer on the electron transport layer.

6. The display panel of claim 1, wherein the light emitting layer covers at least of a portion of the pixel-defining film, and
the electron transport region covers a rest portion of the pixel-defining film which is not covered by the light emitting layer.

7. The display panel of claim 1, wherein the pixel-defining film is an inorganic film.

8. The display panel of claim 1, wherein an angle between a side surface of the light emitting layer and a plane is perpendicular to the plane.

9. The display panel of claim 1, further comprising a thin-film encapsulation layer on the light emitting element layer and configured to cover the light emitting element layer.

10. The display panel of claim 1, further comprising a circuit layer between the base layer and the light emitting element layer.

11. A manufacturing method of a display panel, comprising:
preparing a preliminary display panel including a first electrode and a pixel-defining film having an opening, which defines a pixel region, by exposing a portion of the first electrode;
patterning a light emitting layer and a sacrificial layer on the preliminary display panel to correspond to the pixel region;
removing the sacrificial layer;
forming an electron transport region on the light emitting layer; and
forming a second electrode on the electron transport region,
wherein the electron transport region is entirely formed while covering the pixel-defining film and the light emitting layer.

12. The manufacturing method of claim 11, wherein the second electrode is entirely formed while covering the electron transport region.

13. The manufacturing method of claim 11, further comprising forming a hole transport region on the preliminary display panel to correspond to the pixel region.

14. The manufacturing method of claim 13, wherein the hole transport region comprises a hole injection layer and a hole transport layer.

15. The manufacturing method of claim 11, wherein the patterning of the light emitting layer and the sacrificial layer comprises:
thermally depositing the light emitting layer on the preliminary display panel;
thermally depositing the sacrificial layer on the light emitting layer; and
removing the light emitting layer and the sacrificial layer in a region other than the pixel region through a photoresist process.

16. The manufacturing method of claim 11, wherein the patterning of the light emitting layer and the sacrificial layer is performed in an atmospheric ambient, and
the forming of the electron transport region and the forming of the second electrode are respectively performed in a vacuum.

17. The manufacturing method of claim 11, further comprising, before the forming of the electron transport region on the light emitting layer, removing moisture through heating and drying.

18. The manufacturing method of claim 11, further comprising forming a thin-film encapsulation layer on the second electrode.

19. The manufacturing method of claim 11, wherein the electron transport region comprises an electron injection layer and an electron transport layer.

20. The manufacturing method of claim 11, wherein a side surface of the patterned light emitting layer is perpendicular to a plane.
